(19) United States
(12) Patent Application Publication
(10) Pub. No.: US 2009/0260862 A1
(43) Pub. Date: Oct. 22, 2009

(54) CIRCUIT MODIFICATION DEVICE FOR PRINTED CIRCUIT BOARDS

(76) Inventors: Andrew Yaung, Fremont, CA (US); Neal S. Greenberg, Fremont, CA (US)

Correspondence Address: SCHNECK & SCHNECK, P.O. BOX 2-E, SAN JOSE, CA, 95109-0005, US

(21) Appl. No.: 12/104,330

(22) Filed: Apr. 16, 2008

(51) Int. Cl. H05K 1/11

(52) U.S. Cl. 174/259

(57) ABSTRACT

An electronic circuit modification apparatus to repair or modify portions of a printed circuit board comprises an adhesive layer, an insulating layer formed over the adhesive layer, and a plurality of electrically-conductive traces having an electrically-conductive bonding layer formed thereupon. The electrically-conductive bonding layer is configured to mechanically mount and electrically couple to a lead of an electrical component. At least one masking layer is positioned to electrically isolate the plurality of electrically-conductive traces, one from another.

### TECHNICAL FIELD

The present invention relates generally to printed circuit boards, and more particularly, to a system and method of repairing or modifying a printed circuit board.

### BACKGROUND

Printed circuit boards (PCBs) are a fundamental element in most modern electronic devices. A PCB is used to mechanically support and electrically connect electronic components using conductive pathways, or traces, etched from copper sheets laminated onto a non-conductive substrate. At specified locations on the conductive traces, copper lands, or connection mounting pads, are exposed allowing attachment of electronic devices such as integrated circuits and discrete electronic components such as inductors, capacitors, and resistors.

However, PCBs and related circuits frequently have systematic defects, such as when the boards are not designed or manufactured correctly. Further, manufacturing of very fine circuit conductors in a substrate such as a high density PCB is more prone to defects being inevitably produced as a result of the sheer complexity of such circuits. In other cases, PCB traces are inadvertently cut leaving an electrical opening in the electrical circuit. Either incorrectly designed or incorrectly manufactured boards may contain undesirable short circuits, open circuits, or misrouted traces.

Typical industry practice simply installs jumper wires or deliberately cuts electrical traces as appropriate to correct the defects in the affected PCBs. If the boards are low cost or if repair proves to be too difficult or otherwise uneconomical, the boards may just be scrapped and replaced. However, when the boards are expensive or other circumstances exist that prevent scrapping, the boards must be repaired. When repair is required for a defective group of boards, there are often hundreds or thousands of boards needing attention. In such circumstances, it is advantageous to have repair processes and mechanisms that are as simple, repeatable, and robust as possible. This is especially true if the repair is difficult, such as, for example, rerouting electrical signals under a ball grid array (BGA) component.

Prior art techniques have approached the repair or modification problem from various directions. In one prior art scheme, a conductive metal line is diffusion bonded from a support sheet to an open defect region of the conductor. Specifically, a pattern of conductive lines is formed onto a support sheet from which one line is selectively bonded in position to repair an open defect in a conductor line by the use of a combination of laser energy and ultrasonic energy. The board is concurrently disposed in a liquid in order to remove any metal bridges occurring between conductors without removing repair metal bridges over opens in the conductive lines.

Another prior art method of repairing opens in conductors relies upon filling unwanted gaps in the trace with copper deposited by decomposition of an organo-metallic gas induced by laser-induced chemical vapor deposition. The method has serious deficiencies resulting from the use of cold metal deposition which inhibits the formation of a sound electrically-conductive metallurgical bond. Another problem encountered with the gas decomposition method is the poor mechanical reliability of the repair segment often involving PCB delamination during spin cleaning or thermal cycling of the substrate. Additionally, an additional processing step is required in order to remove any thin contamination or metallic film such as a chromium layer often found on the surface of circuit lines, thereby extending the time required to effect the repair.

Still another prior art technique employs a self-adhesive flex circuit in which a carrier film, such as a Kapton® polyimide film is employed as the top level of the flex circuit. One or more circuit traces run under the carrier film and extend the length of the carrier film. Once the flex circuit is adhered to a PCB requiring repair, the one or more circuit traces are either soldered to the PCB or an electrically conductive adhesive completes the circuit from the flex circuit trace to the PCB.

However, what is needed is a simple, effective, and robust means for effecting repairs and modifications to PCBs without requiring elaborate equipment setups or advanced training to implement.

### SUMMARY

In an exemplary embodiment an electronic circuit modification apparatus is disclosed comprising an adhesive layer, an insulating layer formed over the adhesive layer, and a plurality of electrically-conductive traces having an electrically-conductive bonding layer formed thereupon. The electrically-conductive bonding layer is configured to mechanically mount and electrically couple to a lead of an electrical component. At least one masking layer is positioned to electrically isolate the plurality of electrically-conductive traces, one from another.

In another exemplary embodiment, a flexible circuit for repairing defects in a circuit assembly on a printed circuit board is disclosed. The flexible circuit comprises a pressure-sensitive adhesive layer having a release backing material affixed thereto; the release backing material is configured to be readily removable. An insulating layer is disposed over at least a portion of the pressure-sensitive adhesive layer and a plurality of electrically-conductive traces is formed in contact with at least portions of the insulating layer. Each of the plurality of electrically-conductive traces has an electrically-conductive bonding layer formed thereupon. The electrically-conductive bonding layer is configured to mechanically mount and electrically couple to a lead of an electrical component. At least one masking layer is positioned to electrically isolate the plurality of electrically-conductive traces, one from another.

In another exemplary embodiment, a flexible circuit modification device to repair defects in a circuit assembly on a printed circuit board is disclosed. The flexible circuit comprises a pressure-sensitive adhesive layer having a release backing material affixed thereto with the release backing material configured to be readily removable, an insulating layer disposed over at least a portion of the pressure-sensitive adhesive layer, and a plurality of electrically-conductive traces formed in contact with at least portions of the insulating layer. Each of the plurality of electrically-conductive traces has a solder-laden electrically-conductive bonding layer formed thereupon. The solder-laden electrically-conductive bonding layer is configured to mechanically mount and electrically couple to a lead of an electrical component. At least one masking layer is formed to be at a higher cross-sectional level than an uppermost portion of the electrically-conductive bonding layer thereby forming a trench surrounding each of the solder-laden electrically-conductive bonding layers. The at least one masking layer is arranged to electrically isolate the plurality of electrically-conductive traces, one from another.

### BRIEF DESCRIPTION OF THE DRAWINGS

The appended drawings illustrate exemplary embodiments of the present invention and must not be considered as limiting its scope.

FIG. 1A is a plan view of an exemplary embodiment of a circuit modification device in accordance with the present invention.

FIG. 1B is a first cross-sectional view of an exemplary embodiment of the circuit modification device of FIG. 1A.

FIG. 1C is a second cross-sectional view of another exemplary embodiment of the circuit modification device of FIG. 1A.

FIG. 2 is a perspective view of a portion of an exemplary circuit modification strip in accordance with various embodiments of the present invention.

### DETAILED DESCRIPTION

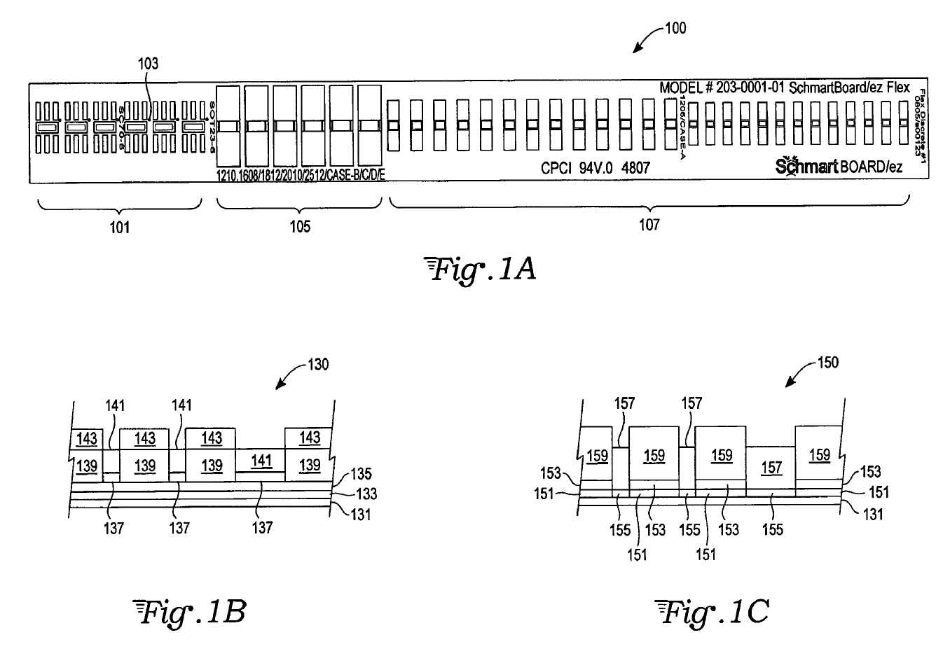

With reference to FIG. 1A, an exemplary circuit modification device comprises a strip 100 for repairing or adding to a printed circuit board. The strip 100 includes an integrated circuit region 101 onto which integrated circuits (not shown) may be mounted. The integrated circuit region 101, as shown, is arranged to accommodate integrated circuit and similar devices with six pins or fewer. A “pin-1” indicator 103 aids in proper orientation of the device. Although not shown, 8-pin or higher dual in-line packages (DIP), pin grid array (PGA), quad flat package (QFP), or various other types of surface mounted devices (SMDs) may be readily accommodated as well. Further, a skilled artisan recognizes that the strip 100 may be designed to mount various other configurations of electronic devices such as controlled collapse chip connection (C4) flip chips, ball grid array (BGA) packaged devices, or a wide variety of other packaging types may all be implemented as well. Further, through holes (not shown) may be disposed on the strip 100 to assist in making electrical connections to leaded devices or jumper wires.

The strip 100 further includes a large two-contact mounting region 105 and a set of smaller two-contact mounting region 107. The large 105 and the set of smaller 107 two-contact mounting regions readily accommodate soldering of discrete surface mount devices such as, for example, thick film surface mount chip resistors or niobium oxide ceramic capacitors in standard EIA case sizes. Additionally, standard discrete wirewound or carbon composition resistors, oscillators, or a variety of other devices may be mounted on the large 105 and the small 107 two-contact mounting regions. Further individual contact pads on the large 105 and the small 107 two-contact mounting regions may be used as bonding sites for jumpers and connections to external devices such as headers (not shown) or for connection to a remote part of the PCB.

The strip 100 may be placed and adhered (by various means discussed in more detail, below) onto the PCB as a single piece. Alternatively, the strip 100 may be cut into appropriate lengths or portions as needed. Each of the cut portions may then be affixed to the PCB where needed. In other alternative embodiments (not shown), the strip 100 may be pre-arranged to be used in a given configuration as a single repair strip to repair a repeating defect or modification made to a series of PCBs.

In FIG. 1B, an exemplary cross-sectional view 130 of a portion of the strip 100 includes a release backing layer 131 and an adhesive layer 133. The adhesive layer 133 may be formed from, for example, 3M™ Adhesive Transfer Tape 467MP, which is a pressure sensitive acrylic adhesive formed on a 58 pound polycoated Kraft paper liner. However, other adhesive strips are known in the art and may readily be utilized as well. The strip 100 adheres to a desired location on the PCB through the adhesive layer 133 once the release backing layer 131 is removed prior to placement of the strip 100 onto a PCB.

With continued reference to FIG. 1B, the strip 100 further includes an insulating layer 135 and a plurality of conductive traces 137. The plurality of conductive traces 137 may be comprised of copper although any conductive material may readily be employed. Standard PCB patterning techniques, known in the art, may be used to pattern the strip 100. Also, exposed copper portions may be plated with solder (discussed below) or other plating materials such as organic surface protectants (OSP), immersion silver, immersion tin, electroless nickel with immersion gold coating, or sputtered gold techniques to prevent copper oxidation.

The strip 100 further includes a masking layer 139, a plurality of solder-laden portions 141, and a solder mask layer 143. Although the masking layer 139 and the solder mask layer 143 are shown separately as unique layers, they may be combined as a single layer.

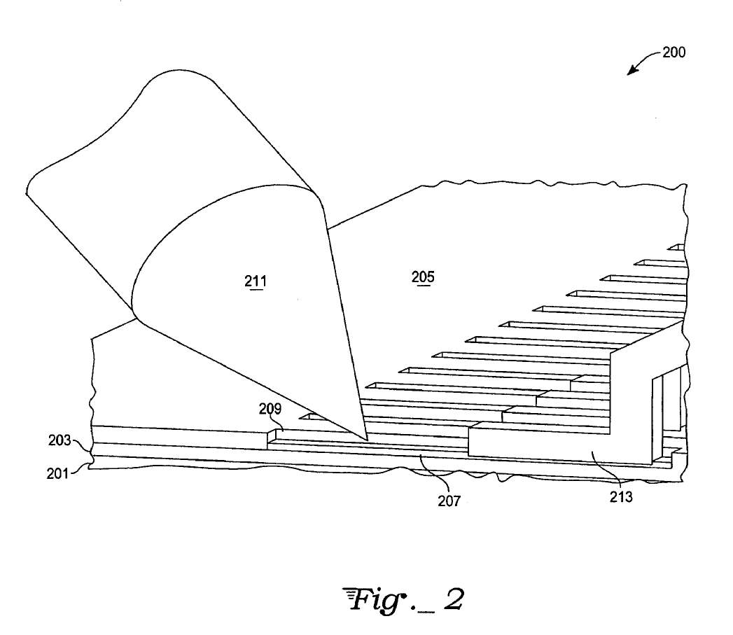

The masking layer 139 provides separation between adjacent conductive areas (i.e., comprised of the solder-laden portions 141 and the underlying conductive traces 137) as well as providing a shallow trench into which solder may be placed. Also, areas that should not be soldered may be covered with, for example a polymer solder resist (solder mask) coating. The solder resist prevents solder from bridging between adjacent conductive areas, thereby preventing short circuits. The solder mask layer 143 serves a similar purpose to the masking layer 139 and, moreover, provides a trench to aid in soldering components and component placement (discussed in more detail below with reference to FIG. 2).

The solder-laden portions 141 may contain a traditional tin/lead type solder, a flux solder, or any type of fusible metal alloy or similar materials. A skilled artisan will recognize that certain types of conductive polymers or adhesives may function properly in many situations as well.

Referring now to FIG. 1C, another exemplary cross-sectional view 150 of a portion of the strip 100 includes the release backing layer 131, as above, a non-continuous adhesive layer 151, and a non-continuous insulating layer 153. Additionally, the exemplary cross-sectional view 150 includes a plurality of solder-laden portions 157 and a solder mask layer 159 with similar functions as the exemplary cross-sectional view 130, above. The solder mask layer 159 may be a single layer as shown or be comprised of a plurality of layers.

The non-continuous adhesive 151 and insulating 153 layers allow a plurality of conductive traces 155 to be electrically exposed on the backside once the release backing paper 131 is removed. Thus, once the strip 100 is placed onto a PCB, any components soldered to the solder-laden portions 157 on the front side of the strip 100 will make electrical contact with the underlying PCB. Alternatively, a layer of solder or other conductive material (not shown) may be used between the conductive traces 155 and the PCB onto which the strip 100 is mounted. The strip may then be permanently bonded to the PCB through an application of thermal energy through, for example, ultrasonic bonding techniques. In yet another alternative embodiment, a plurality of electrical contact lands (not shown) may be formed on the bottom side of the strip 100 to avoid any critical placement of the strip 100 with reference to the underlying PCB.

With reference now to FIG. 2, a portion of a circuit modification device 200 is shown including an insulative substrate 201 formed over an adhesive layer and a release backing layer (neither of which are shown). A plurality of conductive traces 203 is formed over the insulative substrate 201 and capped with a solder mask layer 205. A solder-laden area 207 or another electrically conductive bonding material is formed into each of a plurality of trenches 209 formed from the solder mask layer 205. The plurality of trenches 209 is formed by the solder mask 205 surrounding the solder-laden area 207.

The trench 209 provides mechanical guidance for a soldering tool tip 211 which positions and holds the tip 211 in place while the solder 207 melts. The solder tip 211 thus readily tracks and maintains contact with the solder-laden area 207 at the bottom of the trench 209. In addition to allowing simplified and robust hand soldering, the trench 209 additionally provides a mechanical positioning structure whereby a lead 213 from, for example, an integrated circuit, can be readily positioned and secured.

In a specific exemplary embodiment, the trench 209 is 0.005 inches (approximately 127 μm) deep and the total thickness of the substrate is 0.072 inches (approximately 1.8 mm). The length of the trench 209 is 0.1 inches (2.54 mm) long from the end of the placement of the leads or terminals on the integrated circuit. The trench 209 volume provides sufficient solder to attach the integrated circuit or other electronic component or device to the strip 100.

The present invention is described above with reference to specific embodiments thereof. It will, however, be evident to a skilled artisan that various modifications and changes can be made thereto without departing from the broader spirit and scope of the present invention as set forth in the appended claims. For example, although described herein with reference to a relatively simple circuit or component placement layout, more complex circuits are amenable to forming similar types of circuit modification devices as well. Further, a solder masking layer may be formed to be substantially coplanar with the solder-laden areas. These and various other embodiments are all within a scope of the present invention. The specification and drawings are, accordingly, to be regarded in an illustrative rather than a restrictive sense.

What is claimed is:

1. An electronic circuit modification apparatus, comprising:
an adhesive layer;
an insulating layer formed over the adhesive layer;
a plurality of electrically-conductive traces having an electrically-conductive bonding layer formed thereupon, the electrically-conductive bonding layer configured to mechanically mount and electrically couple to a lead of an electrical component; and
at least one masking layer positioned to electrically isolate the plurality of electrically-conductive traces, one from another.

2. The electronic circuit modification apparatus of claim 1 wherein the adhesive layer is temporarily protected by a removable backing release layer.

3. The electronic circuit modification apparatus of claim 1 wherein the adhesive layer is a pressure-sensitive adhesive.

4. The electronic circuit modification apparatus of claim 1 wherein the electrically-conductive bonding layer comprises solder.

5. The electronic circuit modification apparatus of claim 4 wherein the solder is a tin/lead alloy.

6. The electronic circuit modification apparatus of claim 4 wherein the solder is a flux-core solder.

7. The electronic circuit modification apparatus of claim 4 wherein the solder is a fusible metal alloy.

8. The electronic circuit modification apparatus of claim 1 wherein the electrically-conductive bonding layer comprises an electrically-conductive polymer material.

9. The electronic circuit modification apparatus of claim 1 wherein the at least one masking layer is formed to be at a higher cross-sectional level than an uppermost portion of the electrically-conductive bonding layer.

10. The electronic circuit modification apparatus of claim 1 wherein the at least one masking layer is formed to be substantially coplanar to an uppermost portion of the electrically-conductive bonding layer.

11. The electronic circuit modification apparatus of claim 1 wherein the plurality of electrically-conductive traces are configured to provide electrical coupling from an uppermost portion of the circuit modification apparatus to a lowermost portion of the adhesive layer.

12. The electronic circuit modification apparatus of claim 1 wherein the adhesive layer and the insulating layer are non-continuous thereby allowing at least certain ones of the electrically-conductive traces to provide an electrical coupling path through a cross-sectional thickness of the circuit modification apparatus.

13. A flexible circuit for repairing defects in a circuit assembly on a printed circuit board, the flexible circuit comprising:
a pressure-sensitive adhesive layer having a release backing material affixed thereto, the release backing material configured to be readily removable;
an insulating layer disposed over at least a portion of the pressure-sensitive adhesive layer;
a plurality of electrically-conductive traces formed in contact with at least portions of the insulating layer, each of the plurality of electrically-conductive traces having an electrically-conductive bonding layer formed thereupon, the electrically-conductive bonding layer configured to mechanically mount and electrically couple to a lead of an electrical component; and
at least one masking layer positioned to electrically isolate the plurality of electrically-conductive traces, one from another.

14. The electronic circuit modification apparatus of claim 13 wherein the electrically-conductive bonding layer comprises solder.

15. The electronic circuit modification apparatus of claim 14 wherein the solder is a tin/lead alloy.

16. The electronic circuit modification apparatus of claim 14 wherein the solder is a flux-core solder.

17. The electronic circuit modification apparatus of claim 14 wherein the solder is a fusible metal alloy.

18. The electronic circuit modification apparatus of claim 13 wherein the electrically-conductive bonding layer comprises an electrically-conductive polymer material.

19. The electronic circuit modification apparatus of claim 13 wherein the at least one masking layer is formed to be at a higher cross-sectional level than an uppermost portion of the electrically-conductive bonding layer.

20. The electronic circuit modification apparatus of claim 13 wherein the at least one masking layer is formed to be substantially coplanar to an uppermost portion of the electrically-conductive bonding layer.

21. The electronic circuit modification apparatus of claim 13 wherein the plurality of electrically-conductive traces are configured to provide electrical coupling from an uppermost portion of the circuit modification apparatus to a lowermost portion of the adhesive layer.

22. The electronic circuit modification apparatus of claim 13 wherein the adhesive layer and the insulating layer are non-continuous thereby allowing at least certain ones of the electrically-conductive traces to provide an electrical coupling path through a cross-sectional thickness of the circuit modification apparatus.

23. A flexible circuit modification device to repair defects in a circuit assembly on a printed circuit board, the flexible circuit comprising:
a pressure-sensitive adhesive layer having a release backing material affixed thereto, the release backing material configured to be readily removable;
an insulating layer disposed over at least a portion of the pressure-sensitive adhesive layer;
a plurality of electrically-conductive traces in contact with at least portions of the insulating layer, each of the plurality of electrically-conductive traces having a solder-laden electrically-conductive bonding layer formed thereupon, the solder-laden electrically-conductive bonding layer configured to mechanically mount and electrically couple to a lead of an electrical component; and
at least one masking layer formed to be at a higher cross-sectional level than an uppermost portion of the electrically-conductive bonding layer thereby forming a trench surrounding each of the solder-laden electrically-conductive bonding layers, the at least one masking layer being arranged to electrically isolate the plurality of electrically-conductive traces, one from another.

24. The electronic circuit modification apparatus of claim 23 wherein the solder is a tin/lead alloy.

25. The electronic circuit modification apparatus of claim 23 wherein the solder is a flux-core solder.

26. The electronic circuit modification apparatus of claim 23 wherein the solder is a fusible metal alloy.

27. The electronic circuit modification apparatus of claim 23 wherein the plurality of electrically-conductive traces are configured to provide electrical coupling from an uppermost portion of the circuit modification apparatus to a lowermost portion of the adhesive layer.

28. The electronic circuit modification apparatus of claim 23 wherein the adhesive layer and the insulating layer are non-continuous thereby allowing at least certain ones of the electrically-conductive traces to provide an electrical coupling path through a cross-sectional thickness of the circuit modification apparatus.
